(19) United States
(12) Patent Application Publication
(10) Pub. No.: US 2024/0411520 A1
(43) Pub. Date: Dec. 12, 2024

(54) NEURAL NETWORK COMPUTATION CIRCUIT, CONTROL CIRCUIT THEREFOR, AND CONTROL METHOD THEREFOR

(71) Applicant: Nuvoton Technology Corporation Japan, Kyoto (JP)

(72) Inventors: Masayoshi NAKAYAMA, Kyoto (JP); Hitoshi SUWA, Osaka (JP); Takashi ONO, Osaka (JP); Kazuyuki KOUNO, Osaka (JP); Reiji MOCHIDA, Osaka (JP)

(21) Appl. No.: 18/812,649

(22) Filed: Aug. 22, 2024

Related U.S. Application Data
(63) Continuation of application No. PCT/JP2023/003520, filed on Feb. 3, 2023.

(30) Foreign Application Priority Data
Feb. 28, 2022 (JP) 2022-030315

(51) Int. Cl. G06F 7/544; G11C 11/54; G11C 13/00

(52) U.S. Cl. CPC G06F 7/5443; G11C 11/54; G11C 13/0028; G11C 13/003; G11C 13/0061; G11C 2213/79

(57) ABSTRACT

A neural network computation circuit includes: a plurality of word lines; a plurality of memory cells; a word-line drive circuit; a column selection circuit; a computation circuit that performs neuron computation; a word-line selected-state signal generation circuit; a timing generation circuit; a computation-result processing circuit; and a selected word-line count management circuit that manages a selected word-line count that is information relevant to a total number of word lines that are placed in a selected state when a multiply-accumulate operation is performed, and transmits the selected word-line count to the timing generation circuit. The timing generation circuit sets, according to the selected word-line count, a delay time from when a word-line activation signal is output until when a computation-circuit control signal is output.

### CROSS REFERENCE TO RELATED APPLICATIONS

This is a continuation application of PCT International Application No. PCT/JP2023/003520 filed on Feb. 3, 2023, designating the United States of America, which is based on and claims priority of Japanese Patent Application No. 2022-030315 filed on Feb. 28, 2022. The entire disclosures of the above-identified applications, including the specifications, drawings and claims are incorporated herein by reference in their entirety.

### FIELD

The present disclosure relates to a neural network computation circuit that includes semiconductor storage elements and can achieve reduction in power consumption and large scale integration, a control circuit therefor, and a control method therefor.

### BACKGROUND

Along with development of information communication technology, Internet of Things (IoT) technology with which various things are connected to the Internet has been attracting attention. With the IoT technology, performance of various electronic devices is expected to be improved by the devices being connected to the Internet, but nevertheless, as technology for achieving further improvement in performance, research and development of artificial intelligence (AI) technology that allows electronic devices to train themselves and make determinations have been actively conducted in recent years.

In the AI technology, neural network technology of technologically imitating human brain information processing has been used, and research and development have been actively conducted for semiconductor integrated circuits that perform neural network computation at high speed with low power consumption.

A neural network includes basic elements referred to as neurons (that may also be referred to as perceptrons) connected to inputs by junctions referred to as synapses and having different connection weight coefficients, and can perform advanced computation processing such as image recognition and speech recognition by the neurons being connected to one another. Each neuron performs a multiply-accumulate operation to obtain a sum total of products resulting from multiplying inputs by connection weight coefficients.

Patent Literature (PTL) 1 discloses an example of a neural network computation circuit that includes variable resistance nonvolatile memories (that may be simply referred to as “variable resistance storage elements” hereinafter). This technology configures a neural network computation circuit using variable resistance nonvolatile memories having settable analog resistance values (conductance). With the technology, an analog resistance value (conductance) corresponding to a connection weight coefficient is stored in a nonvolatile memory element, and a value of analogue current flowing through the memory element is utilized according to a selected state of a word line corresponding to an input.

A multiply-accumulate operation performed in a neuron is performed by obtaining, as a result of the multiply-accumulate operation, an analog current value that is a sum of values of current flowing through nonvolatile memory elements that store therein analog resistance values (conductance) corresponding to connection weight coefficients, according to selected states of word lines corresponding to inputs. A neural network computation circuit that includes such nonvolatile memory elements can reduce power consumption, and variable resistance nonvolatile memories having settable analog resistance values (conductance) have been actively developed in recent years.

PTL 2 discloses an example of a semiconductor integrated circuit in which memory cells holding connection weight coefficients can be highly integrated. This semiconductor integrated circuit includes a network-configuration information holding circuit that holds network configuration information that includes address information of memory cells to which connection weight coefficients of a neural network are assigned in a memory array, and can perform computation of an intended neural network configuration by controlling a word-line drive circuit and a column selection circuit when the neural network operates and by causing a computation circuit to operate.

### CITATION LIST

### Patent Literature

PTL 1: International Publication No. WO2019/049741
PTL 2: International Publication No. WO2019/049686

### SUMMARY

### Technical Problem

However, the configurations disclosed in PTL 1 and PTL 2 have a problem that it is difficult to increase the speed of neuron computation operation.

In view of this, the present disclosure has been conceived in light of the above-stated problem, and is to provide a neural network computation circuit that can perform neuron computation at high speed, a control circuit therefor, and a control method therefor.

### Solution to Problem

In order to address the problem as stated above, a neural network computation circuit according to an aspect of the present disclosure includes: a plurality of word lines; a plurality of bit lines crossing the plurality of word lines; a plurality of memory cells disposed at intersections of the plurality of word lines and the plurality of bit lines, the plurality of memory cells including a plurality of semiconductor storage elements each holding a connection weight coefficient of a neural network; a word-line drive circuit capable of driving one or more word lines to be placed in a selected state, out of the plurality of word lines; a column selection circuit capable of selecting one or more bit lines from among the plurality of bit lines; a computation circuit that performs, by using current flowing through the one or more bit lines selected by the column selection circuit, a multiply-accumulate operation on connection weight coefficients held in two or more memory cells and input data represented by driven states of the plurality of word lines, and performs neuron computation by performing computation processing of an activation function on a result of the multiply-accumulate operation, the two or more memory cells being included in the plurality of memory cells and connected to the one or more bit lines selected by the column selection circuit; a word-line selected-state signal generation circuit that generates a word-line selected-state signal indicating the one or more word lines to be placed in the selected state by the word-line drive circuit; a timing generation circuit that outputs: a word-line activation signal for activating the word-line drive circuit, based on the word-line selected-state signal; a column selection signal for driving the column selection circuit; and a computation-circuit control signal for activating the computation circuit; a computation-result processing circuit that processes a computation result that is an output from the computation circuit; and a selected word-line count management circuit that manages a selected word-line count that is information relevant to a total number of the one or more word lines that are placed in the selected state when the computation circuit performs the multiply-accumulate operation, and transmits the selected word-line count to the timing generation circuit. The timing generation circuit sets, according to the selected word-line count, a delay time from when the word-line activation signal is output until when the computation-circuit control signal is output.

In order to address the problem as stated above, a control circuit for a neural network computation circuit according to an aspect of the present disclosure is a control circuit that controls a neural network computation circuit, the control circuit including: the word-line selected-state signal generation circuit, the timing generation circuit, the computation-result processing circuit, and the selected word-line count management circuit that are included in the neural network computation circuit stated above. The timing generation circuit sets, according to the selected word-line count, the delay time from when the word-line activation signal is output until when the computation-circuit control signal is output.

In order to address the problem as stated above, a control method for a neural network computation circuit according to an aspect of the present disclosure is a control method for a neural network computation circuit that includes: a plurality of word lines; a plurality of bit lines crossing the plurality of word lines; a plurality of memory cells disposed at intersections of the plurality of word lines and the plurality of bit lines, the plurality of memory cells including a plurality of semiconductor storage elements each holding a connection weight coefficient of a neural network; a word-line drive circuit capable of driving one or more word lines to be placed in a selected state, out of the plurality of word lines; a column selection circuit capable of selecting one or more bit lines from among the plurality of bit lines; and a computation circuit that performs, by using current flowing through the one or more bit lines selected by the column selection circuit, a multiply-accumulate operation on input data represented by driven states of the plurality of word lines, and performs neuron computation by performing computation processing of an activation function on a result of the multiply-accumulate operation, the control method including: setting a word-line selected state when the one or more word lines are driven to be placed in the selected state, out of the plurality of word lines; setting a delay time according to a selected word-line count that is information relevant to a total number of the one or more word lines that are placed in the selected state when the multiply-accumulate operation is performed; driving the one or more word lines according to the word-line selected state; and activating the computation circuit. The delay time is a period from when the driving is performed until when the activating is performed.

### Advantageous Effects

Neuron computation can be performed at high speed by using a neural network computation circuit, a control circuit therefor, and a control method therefor according to the present disclosure.

### BRIEF DESCRIPTION OF DRAWINGS

These and other advantages and features will become apparent from the following description thereof taken in conjunction with the accompanying Drawings, by way of non-limiting examples of embodiments disclosed herein.

FIG. 1 illustrates an example of a configuration of a neural network.

FIG. 2 illustrates a neuron in neural network computation.

FIG. 3 illustrates mathematical expressions calculated by the neuron illustrated in FIG. 2.

FIG. 4 illustrates a step function that is an example of an activation function of a neuron in neural network computation.

FIG. 5 is a block diagram illustrating a configuration of a neural network computation circuit according to Embodiment 1.

FIG. 6 illustrates an example of a configuration of a memory array included in the neural network computation circuit illustrated in FIG. 5.

FIG. 7 illustrates an example of a configuration of a memory cell illustrated in FIG. 6.

FIG. 8 is a block diagram illustrating an example of a configuration of a control circuit included in the neural network computation circuit illustrated in FIG. 5.

FIG. 9 illustrates an example of a configuration of a word-line drive circuit included in the neural network computation circuit illustrated in FIG. 5, plural word lines, and a driver power supply.

FIG. 10 illustrates operation of selecting one word line by the word-line drive circuit illustrated in FIG. 9.

FIG. 11 illustrates operation of selecting k word lines by the word-line drive circuit illustrated in FIG. 9.

FIG. 12 illustrates a relation between the number of word lines selected by the word-line drive circuit (selected WL count) illustrated in FIG. 9 and delay time Tset for set-up of word lines.

FIG. 13 illustrates an example of a configuration in the case where four computation circuits are provided in the neural network computation circuit illustrated in FIG. 5.

FIG. 14 illustrates a specific example of a neural network configuration in which the neural network computation circuit according to Embodiment 1 is used.

FIG. 15 illustrates examples of output data from an input layer, a hidden layer, and an output layer of the neural network illustrated in FIG. 14.

FIG. 16 illustrates operation waveforms of the hidden layer, which are obtained using the neural network computation circuit according to Embodiment 1.

FIG. 17 illustrates operation waveforms of the output layer, which are obtained using the neural network computation circuit according to Embodiment 1.

FIG. 18 illustrates an operation flow of the neural network computation circuit according to Embodiment 1.

FIG. 19 illustrates an example of a configuration of a control circuit included in a neural network computation circuit according to Embodiment 2.

FIG. 20 illustrates an example of network configuration information stored in a network-configuration information holding circuit included in the control circuit illustrated in FIG. 19.

FIG. 21 illustrates operation waveforms of the hidden layer, which are obtained using the neural network computation circuit according to Embodiment 2.

FIG. 22 illustrates operation waveforms of the output layer, which are obtained using the neural network computation circuit according to Embodiment 2.

FIG. 23 illustrates an operation flow of the neural network computation circuit according to Embodiment 2.

### DESCRIPTION OF EMBODIMENTS

### (Knowledge Obtained by the Present Inventors)

The configurations disclosed in PTL 1 and PTL 2 stated above have a problem as follows.

Specifically, when neural network computation is performed, plural word lines corresponding to input states of a neuron need to be selected at one time, but nevertheless a power source potential of plural word line drivers is decreased due to the operation of the word line drivers when the word lines are driven, and a set-up time for the word lines until when charge is supplied from a power source circuit is necessary. The set-up time increases with an increase in the number of word lines selected at the same time.

Accordingly, in order to achieve an intended neural network configuration and an operation based on inputs to a neuron, it has been necessary to set a fixed long delay time corresponding to the set-up time for word lines corresponding in total number to the word lines of a memory array provided and thereafter drive a computation circuit, and thus it is difficult to increase the speed of the computation operation of neurons.

In view of this, the present inventors provided a neural network computation circuit with a control circuit that includes a selected word-line count management circuit that manages a selected word-line count that is information relevant to a total number of word lines placed in a selected state when a multiply-accumulate operation is performed, and a timing generation circuit that sets a delay time from when a word-line activation signal for activating a word-line drive circuit is output until when a computation-circuit control signal for activating a computation circuit is output.

Accordingly, the delay time is dynamically determined according to the actual number of selected word lines, and thus this eliminates the necessity to set a fixed long delay time as conventional technology required. Hence, a neural network computation circuit that can perform neuron computation at high speed, a control circuit therefor, and a control method therefor can be provided.

### EMBODIMENTS

In the following, embodiments according to the present disclosure are to be described with reference to the drawings. Note that the embodiments described below each show a specific example of the present disclosure. The numerical values, shapes, materials, elements, the arrangement and connection of the elements, steps, and the processing order of the steps, for instance, shown in the following embodiments are mere examples, and therefore are not intended to limit the scope of the present disclosure. Furthermore, the drawings do not necessarily provide strictly accurate illustration. In the drawings, the same numeral is given to substantially the same configuration, and a redundant description thereof may be omitted or simplified. Moreover, “being connected” means electrical connection, and also includes not only the case where two circuit elements are directly connected, but also the case where two circuit elements are indirectly connected in a state in which another circuit element is provided between the two circuit elements.

### <Neural Network Computation>

First, basic theory of neural network computation is to be described.

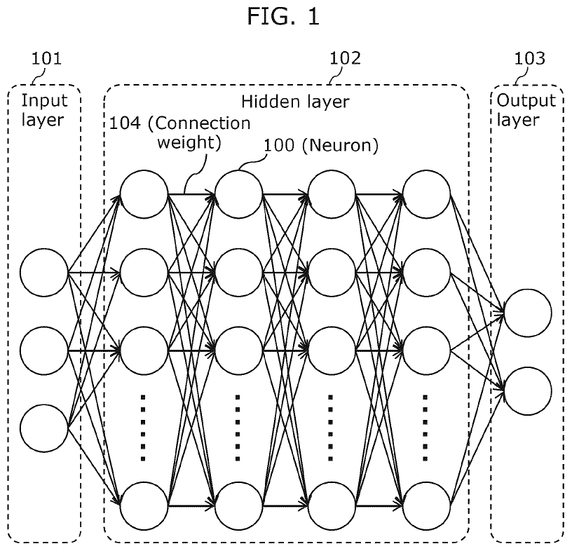

FIG. 1 illustrates an example of a configuration of a neural network (a deep neural network, herein). The neural network includes input layer 101 to which input data is input, hidden layer 102 (which may also be referred to as an intermediate layer) that receives input data from input layer 101 and performs computation processing thereon, and output layer 103 that receives output data from hidden layer 102 and performs computation processing thereon.

In each of input layer 101, hidden layer 102, and output layer 103, a large number of basic elements of a neural network referred to as neurons 100 are present, and neurons 100 are connected via connection weights 104. Connection weights 104 have different connection weight coefficients and connect neurons 100. Input data items are input to neuron 100, and neuron 100 performs a multiply-accumulate operation on the input data items and corresponding connection weight coefficients, and output the result as output data. Here, hidden layer 102 is configured by connecting neurons in plural layers (four layers in FIG. 1), and a neural network as illustrated in FIG. 1 is referred to as a deep neural network from the meaning that a deep neural network is formed.

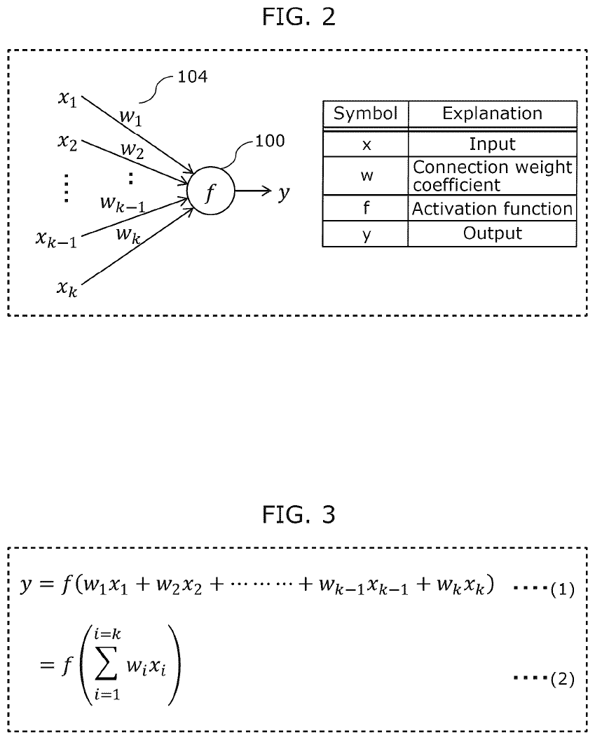

FIG. 2 illustrates a neuron in neural network computation. FIG. 3 illustrates mathematical expressions calculated by neuron 100 illustrated in FIG. 2. To neuron 100, k inputs x1 to xk are connected with connection weights having connection weight coefficients w1 to wk, and neuron 100 performs a multiply-accumulate operation on inputs x1 to xk and connection weight coefficients w1 to wk. Furthermore, neuron 100 has activation function f, and performs computation processing of the activation function on the result of the multiply-accumulate operation and outputs output y.

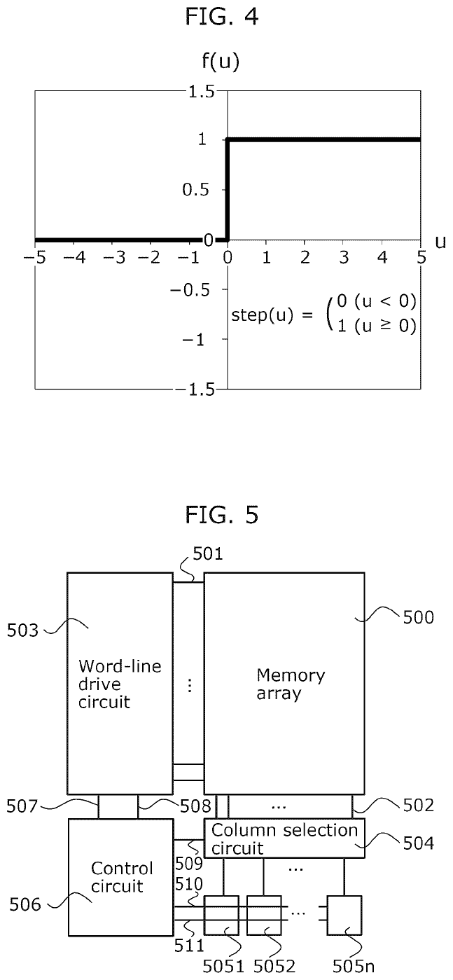

FIG. 4 illustrates a step function that is an example of activation function f of a neuron in neural network computation. The horizontal axis represents input u of activation function f, whereas the vertical axis represents output f(u) of activation function f. As illustrated in FIG. 4, the step function outputs output f(u)=0 when input u has a negative value (<0), and outputs output f(u)=1 when input u has a positive value (≥0). When activation function f that is a step function is used, neuron 100 in FIG. 2 described above outputs output y=0 when the result of a multiply-accumulate operation on inputs x0 to xn and connection weight coefficients w0 to wn is a negative value, and outputs output y=1 when the result of the multiply-accumulate operation is a positive value.

### Embodiment 1

FIG. 5 is a block diagram illustrating a configuration of a neural network computation circuit according to Embodiment 1. The neural network computation circuit includes memory array 500 in which memory cells connected to plural word lines 501 and plural bit lines 502 are disposed in a matrix, word-line drive circuit 503 that places one or more word lines in a selected or non-selected state, n computation circuits 5051 to 505n where n is an integer of 1 or more, column selection circuit 504 that selects one or more bit lines out of plural bit lines 502 and connects the selected one or more bit lines to n computation circuits 5051 to 505n, and control circuit 506.

Computation circuits 5051 to 505n perform, using current flowing through one or more bit lines 502 selected by column selection circuit 504, a multiply-accumulate operation on connection weight coefficients held in memory cells connected to one or more bit lines 502 selected by column selection circuit 504 and input data represented by driven states of word lines 501, and perform neuron computation by performing computation processing of an activation function.

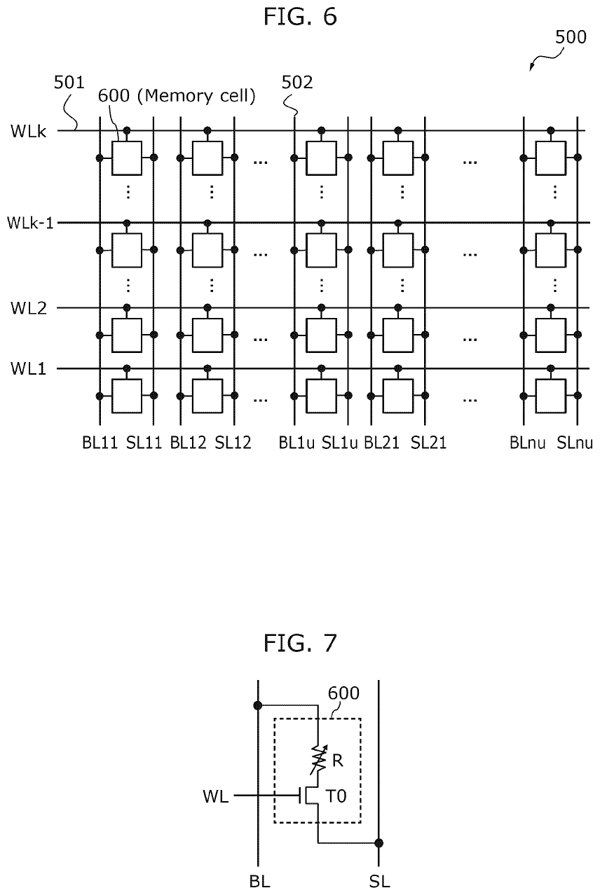

FIG. 6 illustrates an example of a configuration of memory array 500 included in the neural network computation circuit illustrated in FIG. 5. Memory cells 600 are disposed in a matrix, which are semiconductor storage elements connected to plural word lines 501 (WLk, . . . , WLk−1, . . . , WL2, and WL1) and plural bit lines 502 (BL11, BL12, . . . , BL1u, BL21, . . . BLnu).

Word lines 501 are one or more k word lines where k is an integer of 1 or more.

Bit lines 502 are logically divided into n in units of one or more u bit lines where u is an integer of 1 or more, and column selection circuit 504 connects one or more of the divided bit lines to each of n computation circuits 5051 to 505n.

For example, one or more bit lines out of u bit lines BL11 to BL1u are connected to computation circuit 5051, one or more bit lines out of u bit lines BL21 to BL2u are connected to computation circuit 5052, and the same applies to the remaining, so one or more bit lines out of u bit lines BLn1 to BLnu are connected to computation circuit 505n.

FIG. 7 illustrates an example of a configuration of memory cell 600 illustrated in FIG. 6. Memory cell 600 is a memory cell (resistive random access memory (ReRAM)) in which transistor TO that includes a gate to which a word line is connected and variable-resistance storage element R are connected in series. Bit line BL is connected to one end of variable-resistance storage element R, and source line SL is connected to one end of transistor TO.

Variable-resistance storage element R stores therein a connection weight coefficient of a neuron as a resistance value, and the resistance value is set by a write circuit not illustrated in FIG. 5 and stored. Note that in the example in FIG. 7, a variable-resistance storage element (ReRAM) is used as memory cell 600, but another nonvolatile storage element such as, for example, a magnetoresistance storage element (MRAM) or phase-change resistance storage element (PRAM) may be used, or a charge storage element having a threshold that changes according to the amount of charge stored in a flash memory, for instance.

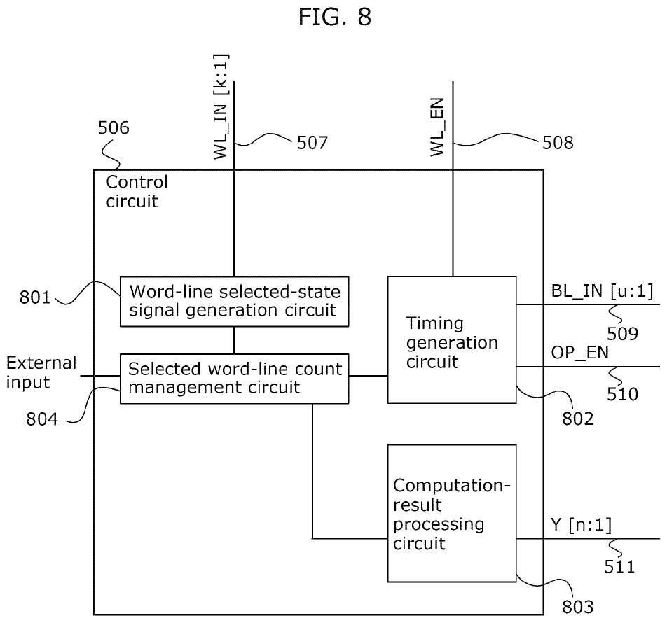

FIG. 8 is a block diagram illustrating a configuration of control circuit 506 included in the neural network computation circuit illustrated in FIG. 5. Control circuit 506 includes word-line selected-state signal generation circuit 801, timing generation circuit 802, computation-result processing circuit 803, and selected word-line count management circuit 804.

Word-line selected-state signal generation circuit 801 generates word-line selected-state signal 507 (WL_IN [k:1]) for selection by word-line drive circuit 503.

Computation-result processing circuit 803 uses n computation results 511 (Y [n:1]) indicating “0” or “1”, which are obtained by computation circuits 5051 to 505n, as a result of computation obtained by the hidden layer or the output layer of the neural network. If the result is a computation result of the hidden layer, computation-result processing circuit 803 processes the result as input data for a subsequent layer connected to the hidden layer, and if the result is a computation result of the output layer, outputs the result as a result of operation of the neural network.

Selected word-line count management circuit 804 receives input data from the input layer of the neural network or a result of processing by computation-result processing circuit 803 as input data, and transmits, to word-line selected-state signal generation circuit 801, the input data as data indicating word lines selected when a multiply-accumulate operation is performed. Selected word-line count management circuit 804 counts the number of bits indicating selected states of word lines, which are included in the data (here, a line is selected in the case of “1”), as a selected word-line count, and transmits the selected word-line count to timing generation circuit 802.

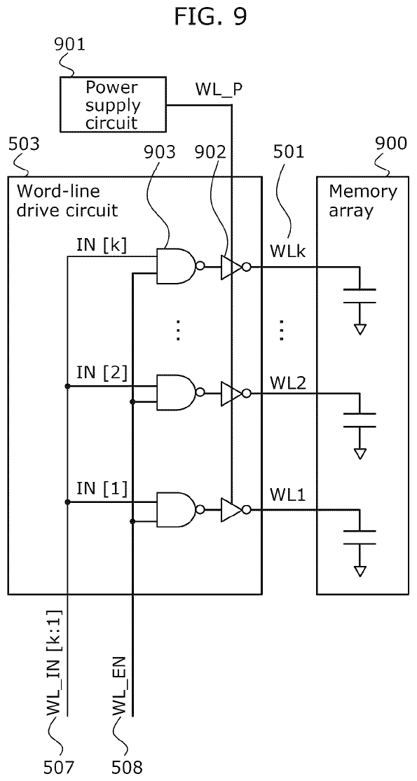

Here, FIG. 9 illustrates memory array 900 in which word line loads driven by word-line drive circuit 503 as capacitor loads are shown in a simplified manner, among word-line drive circuit 503, plural word lines 501, and memory array 500 that are included in the neural network computation circuit illustrated in FIG. 5.

Word-line drive circuit 503 includes NAND gates 903 and word-line drivers 902 which are in one-to-one correspondence to plural word lines 501, and selects, using word-line drivers 902, word lines WL1 to WLk, based on word-line selected-state signal 507 (WL_IN [k:1]) and word-line activation signal 508 (WL_EN). Power supply (WL_P) for word-line drivers 902 when selecting word lines is provided within a chip or by external power supply circuit 901.

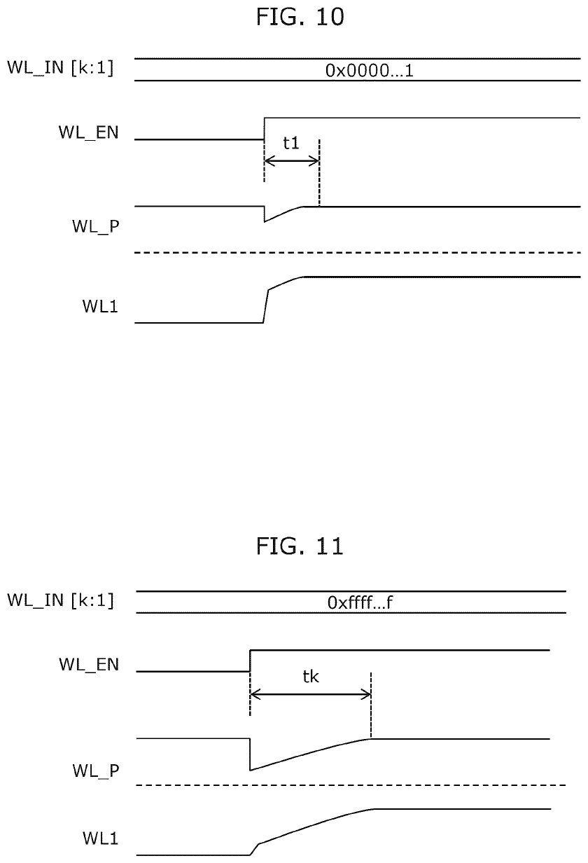

FIG. 10 illustrates operation of word-line drive circuit 503 when one word line WL1 is selected in the configuration in FIG. 9, whereas FIG. 11 illustrates operation of word-line drive circuit 503 when a maximum of k word lines WL1 to WLk are selected.

As can be seen from FIG. 10, word-line activation signal 508 (WL_EN) transitions to the high state, word-line driver 902 charges word line WL1, and charge in driver power supply (WL_P) is consumed. Consequently, the power supply potential of power supply WL_P is decreased and thereafter is restored by charge being supplied from power supply circuit 901. Hence, delay time t1 is necessary as a set-up time for selected word line WL1.

An amount of decrease in power supply potential and time for restoring the power supply potential by charge being supplied differ depending on the number of word lines selected, and as illustrated in FIG. 11, when k word lines are selected where k denotes the maximum count, a decrease in power supply potential increases and longer delay time tk than t1 is used as the set-up time for selected word lines WL1 to WLk.

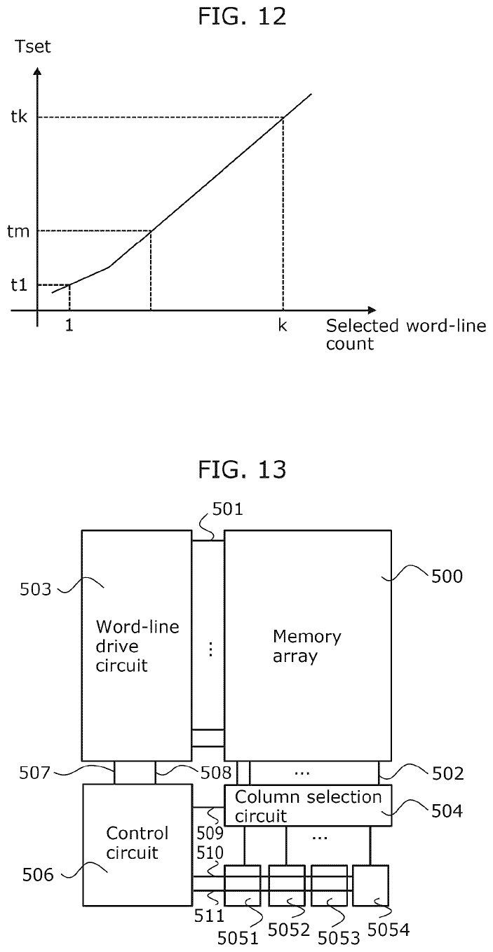

FIG. 12 illustrates a relation between the number of word lines selected by word-line drive circuit 503 (“Selected word-line count”) illustrated in FIG. 9 and a delay time (“Tset”) corresponding to a time to be used for set-up of one or more word lines. Delay time Tset increases with an increase in the selected word-line count.

Timing generation circuit 802 generates word-line activation signal 508 (WL_EN) and column selection signal 509 (BL_IN [u:1]) for column selection circuit 504 to connect plural bit lines 502 and computation circuits 5051 to 505n, and generates computation-circuit control signal 510 (OP_EN) after a lapse of delay time Tset corresponding to the set-up time for word lines.

Here, timing generation circuit 802 sets delay time Tset based on a relation (FIG. 12) between the selected word-line count obtained by selected word-line count management circuit 804 and a start-up time therefor.

Next, examples of specific operations using the neural network computation circuit according to Embodiment 1 are to be described with reference to FIG. 8 and FIG. 13 to FIG. 17.

FIG. 13 illustrates the case where four computation circuits (5051 to 5054) are provided in the configuration of the neural network computation circuit illustrated in FIG. 5. The other configuration is the same as the configuration in FIG. 5.

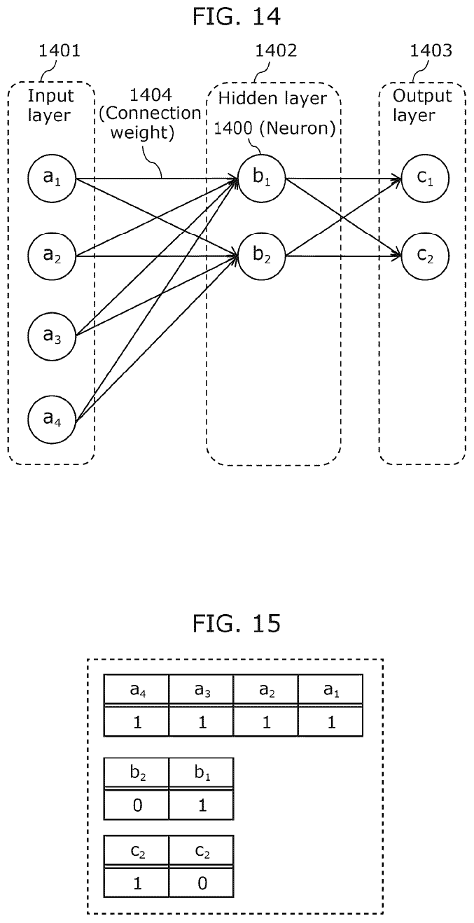

FIG. 14 illustrates a specific example of a neural network configuration in which the neural network computation circuit according to Embodiment 1 is used. Here, an example of a specific neural network configuration in the examples of operations described in the following is shown, and input layer 1401 includes four nodes a1 to a4, hidden layer 1402 includes two nodes b1 and b2, and output layer 1403 includes two nodes c1 and c2. In each of input layer 1401, hidden layer 1402, and output layer 1403, a large number of basic elements of a neural network referred to as neurons 1400 are present, and neurons 1400 are connected via connection weights 1404. Connection weights 1404 have different connection weight coefficients and connect neurons 1400.

FIG. 15 illustrates examples of output data from input layer 1401, hidden layer 1402, and output layer 1403 of the neural network illustrated in FIG. 14. Here, results of computations at nodes a1 to a4 in input layer 1401, nodes b1 and b2 in hidden layer 1402, and nodes c1 and c2 in output layer 1403 are shown.

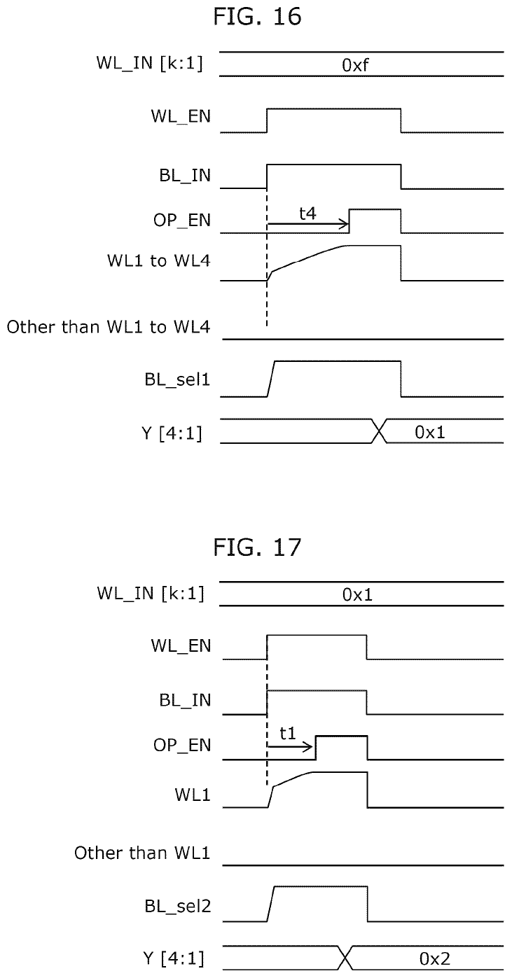

FIG. 16 illustrates operation waveforms (or stated differently, signal waveforms) of hidden layer 1402, which are obtained using the neural network computation circuit according to Embodiment 1. Here, the drawing shows operation waveforms in the case where the neural network computation circuit in FIG. 13 is used for the computation operation of hidden layer 1402 in the neural network configuration in FIG. 14, and the case where input data when the computation operation of hidden layer 1402 is performed is (a4, a3, a2, a1)=(1, 1, 1, 1) illustrated in FIG. 15.

Signal BL_sel1 represents a bit line selected from among plural bit lines 502 when hidden layer 1402 performs a computation operation.

Signal Y [4:1] represents computation results 511 of “0” or “1” of computation circuits 5051 to 5054, and with regard to four signals represented by Y [4:1], Y [4] corresponds to computation result 511 of computation circuit 5054, Y [3] corresponds to computation result 511 of computation circuit 5053, Y [2] corresponds to computation result 511 of computation circuit 5052, and Y [1] corresponds to computation result 511 of computation circuit 5051.

Selected word-line count management circuit 804 receives data corresponding to input data items a1 to a4 from an external input, and outputs word-line selected-state signal WL_IN [k:1]=0xf to word-line drive circuit 503 via word-line selected-state signal generation circuit 801. Selected word-line count management circuit 804 counts the number of data items (“1”) corresponding to word-line (WL) selecting and included in input data items a1 to a4, and transmits the counted number to timing generation circuit 802 as a selected word-line count (four).

Timing generation circuit 802 sets delay time t4 corresponding to a set-up time for a selected word-line count (four), word-line activation signal WL_EN is transitioned to a high state, to cause word-line drive circuit 503 to start selecting four word lines WL1 to WL4, and also out of column selection signals BL_IN [u:1], signals corresponding to one or more bit lines BL_sel1 that are selected are transitioned to the high state to cause column selection circuit 504 to start selecting bit line BL_sel1. After that, timing generation circuit 802 causes computation-circuit control signal OP_EN to the high state after a lapse of delay time t4 that has been set, to activate computation circuits 5051 to 5054.

Computation circuits 5051 to 5054 perform a multiply-accumulate operation using current flowing according to the resistance values stored as connection weight coefficients in memory cells 600 disposed at intersections of selected word lines WL1 to WL4 and selected bit line BL_sel1, and further outputs computation result Y [4:1]=0x1 by performing computation processing of an activation function.

FIG. 17 illustrates operation waveforms (or stated differently, signal waveforms) of output layer 1403, which are obtained using the neural network computation circuit according to Embodiment 1. Here, the drawing shows operation waveforms of output layer 1403 in the case where the neural network computation circuit in FIG. 13 is used for the computation operation of output layer 1403 in the neural network configuration in FIG. 14, and the case where input data when the computation operation of output layer 1403 is performed is (b2, b1)=(0, 1) illustrated in FIG. 15, which is the computation result of hidden layer 1402.

Signal BL_sel2 represents a bit line selected from among plural bit lines 502 when output layer 1403 performs a computation operation.

Selected word-line count management circuit 804 receives data corresponding to input data items b1 and b2 from computation-result processing circuit 803, and outputs word-line selected-state signal WL_IN [k:1]=0x1 to word-line drive circuit 503 via word-line selected-state signal generation circuit 801. Selected word-line count management circuit 804 counts the number of data items (“1”) corresponding to WL selecting and included in input data items b1 and b2, and transmits the counted number to timing generation circuit 802 as a selected word-line count (one).

Timing generation circuit 802 sets delay time t1 corresponding to a set-up time for the selected word-line count (one), word-line activation signal WL_EN is transitioned to a high state, to start selecting word line WL2, and also out of column selection signals BL_IN [u:1], signals corresponding to one or more bit lines (BL_sel2) that are selected are transitioned to the high state to start selecting bit line BL_sel2. After that, timing generation circuit 802 causes computation-circuit control signal OP_EN to the high state after a lapse of delay time t1 that has been set, to activate computation circuits 5051 to 5054.

Computation circuits 5051 to 5054 perform a multiply-accumulate operation using current flowing according to the resistance values stored as connection weight coefficients in memory cells 600 disposed at intersections of selected word line WL1 and selected one or more bit lines BL_sel2 and further performs computation processing of an activation function, to output computation result Y [4:1]=0x2.

Computation-result processing circuit 803 receives and outputs computation result 511, to the outside, as the result of the neural network operation in FIG. 14.

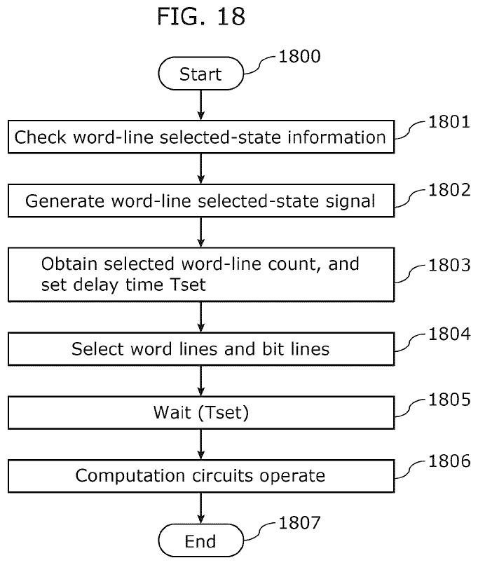

FIG. 18 illustrates an operation flow (that is a control method for a neural network computation circuit) of a neural network operation performed using the neural network computation circuit according to Embodiment 1.

After operation starts (1800), selected word-line count management circuit 804 checks word-line selected-state information determined by an external input or a computation result of a previous layer that is an input for a layer for which computation operation is to be performed (1801).

Based on the result, word-line selected-state signal generation circuit 801 generates word-line selected-state signal 507 for determining which word line is to be selected from among plural word lines in the memory array, and outputs the signal to word-line drive circuit 503 (1802).

Next, selected word-line count management circuit 804 counts the number of word lines to be selected from the word-line selected-state information, and outputs the number as a selected word-line count to timing generation circuit 802, and thus timing generation circuit 802 sets delay time Tset as a word-line set-up time according to the selected word-line count received (1803). Then, timing generation circuit 802 outputs word-line activation signal 508 to word-line drive circuit 503 and furthermore outputs column selection signal 509 to column selection circuit 504, and outputs computation-circuit control signal 510 to computation circuits 5051 to 5054 after a lapse of delay time Tset that has been set.

As a result, word-line drive circuit 503 that has received word-line selected-state signal 507 and word-line activation signal 508 selects one or more word lines, and column selection circuit 504 that has received bit-line selection information not illustrated and column selection signal 509 selects one or more bit lines (1804).

Then, after waiting delay time Tset (1805), computation circuits 5051 to 5054 operate (1806) and output computation results 511, so that processing ends (1807).

Through the above operation, delay time Tset until computation circuits 5051 to 5054 are activated after plural word lines for the neural network in FIG. 14 to operate are selected is changed according to the number of word lines that are selected in an actual operation. Hence, it is unnecessary to set, as a delay time, a fixed long set-up time for which a total number of word lines of memory array 900 is taken into consideration as with the conventional technology, and thus computation operation of neurons 1400 can be performed at high speed.

As described above, a neural network computation circuit according to the present embodiment includes: a plurality of word lines 501; a plurality of bit lines 502 crossing the plurality of word lines 501; a plurality of memory cells 600 disposed at intersections of the plurality of word lines 501 and the plurality of bit lines 502, the plurality of memory cells 600 including a plurality of semiconductor storage elements each holding a connection weight coefficient of a neural network; word-line drive circuit 503 capable of driving one or more word lines 501 to be placed in a selected state, out of the plurality of word lines 501; column selection circuit 504 capable of selecting one or more bit lines 502 from among the plurality of bit lines 502; computation circuits 5051 to 505n that perform, by using current flowing through one or more bit lines 502 selected by column selection circuit 504, a multiply-accumulate operation on connection weight coefficients held in two or more memory cells 600 and input data represented by driven states of the plurality of word lines 501, and perform neuron computation by performing computation processing of an activation function on a result of the multiply-accumulate operation, two or more memory cells 600 being included in the plurality of memory cells 600 and connected to one or more bit lines 502 selected by column selection circuit 504; word-line selected-state signal generation circuit 801 that generates word-line selected-state signal 507 indicating one or more word lines 501 to be placed in the selected state by word-line drive circuit 503; timing generation circuit 802 that outputs: word-line activation signal 508 for activating word-line drive circuit 503, based on word-line selected-state signal 507; column selection signal 509 for driving column selection circuit 504; and computation-circuit control signal 510 for activating computation circuits 5051 to 505n; computation-result processing circuit 803 that processes computation result 511 that is an output from computation circuits 5051 to 505n; and selected word-line count management circuit 804 that manages a selected word-line count that is information relevant to a total number of one or more word lines 501 that are placed in the selected state when the computation circuit performs the multiply-accumulate operation, and transmits the selected word-line count to timing generation circuit 802. Timing generation circuit 802 sets, according to the selected word-line count, a delay time from when word-line activation signal 508 is output until when computation-circuit control signal 510 is output.

Accordingly, the delay time until when the computation circuit is activated after word lines are selected is changed according to a selected word-line count that is information relevant to the number of word lines that are actually placed in the selected state, and thus this eliminates the necessity to set, as the delay time, a fixed long set-up time according to the total number of word lines in a memory array as conventional technology required, so that neuron computation is performed at high speed.

Here, specifically, the selected word-line count is a value obtained by selected word-line count management circuit 804 counting the total number of one or more word lines 501 placed in the selected state, the total number being included in data that is input from an outside of the neural network computation circuit or in output data from computation-result processing circuit 803. Accordingly, a delay time according to the number of word lines that are actually placed in the selected state is set.

Memory cells 600 each include a variable-resistance storage element, a magnetoresistance storage element, a phase-change storage element, or a charge storage element having a threshold that changes according to an amount of charge stored. Accordingly, the memory cells are embodied by nonvolatile storage elements, and keep holding storage information even if supply of power is stopped.

Control circuit 506 that controls the neural network computation circuit according to the present embodiment includes: word-line selected-state signal generation circuit 801, timing generation circuit 802, computation-result processing circuit 803, and selected word-line count management circuit 804 that are included in the neural network computation circuit stated above. Timing generation circuit 802 sets, according to the selected word-line count, the delay time from when word-line activation signal 508 is output until when computation-circuit control signal 510 is output.

A control method for a neural network computation circuit according to the present embodiment is a control method for a neural network computation circuit that includes: a plurality of word lines 501; a plurality of bit lines 502 crossing the plurality of word lines 501; a plurality of memory cells 600 disposed at intersections of the plurality of word lines 501 and the plurality of bit lines 502, the plurality of memory cells 600 including a plurality of semiconductor storage elements each holding a connection weight coefficient of a neural network; word-line drive circuit 503 capable of driving one or more word lines 501 to be placed in a selected state, out of the plurality of word lines 501; column selection circuit 504 capable of selecting one or more bit lines 502 from among the plurality of bit lines 502; and computation circuits 5051 to 505n that perform, by using current flowing through one or more bit lines 502 selected by column selection circuit 504, a multiply-accumulate operation on input data represented by driven states of the plurality of word lines 501, and perform neuron computation by performing computation processing of an activation function on a result of the multiply-accumulate operation, the control method including: setting a word-line selected state when one or more word lines 501 are driven to be placed in the selected state, out of the plurality of word lines 501; setting a delay time according to a selected word-line count that is information relevant to a total number of one or more word lines 501 that are placed in the selected state when the multiply-accumulate operation is performed; driving one or more word lines 501 according to the word-line selected state; and activating computation circuits 5051 to 505n. The delay time is a period from when the driving is performed until when the activating is performed.

Accordingly, the delay time until when the computation circuit is activated after word lines are selected is changed according to a selected word-line count that is information relevant to the number of word lines that are actually placed in the selected state, and thus this eliminates the necessity to set, as the delay time, a fixed long set-up time according to the total number of word lines in a memory array as conventional technology required, so that neuron computation is performed at high speed.

Here, the selected word-line count is a total number of one or more word lines 501 to be placed in the selected state, one or more word lines 501 being included in the word-line selected state. Accordingly, the delay time according to the number of word lines that are actually placed in the selected state is set.

### Embodiment 2

Next, a neural network computation circuit according to Embodiment 2 is to be described. The neural network computation circuit according to the present embodiment basically has the same configuration as the configuration of the neural network computation circuit according to Embodiment 1 illustrated in FIG. 5. Note that the configuration of the control circuit is different from that in Embodiment 1. Hereinafter, a control circuit according to the present embodiment is referred to as control circuit 506a, and different points from Embodiment 1 are mainly described.

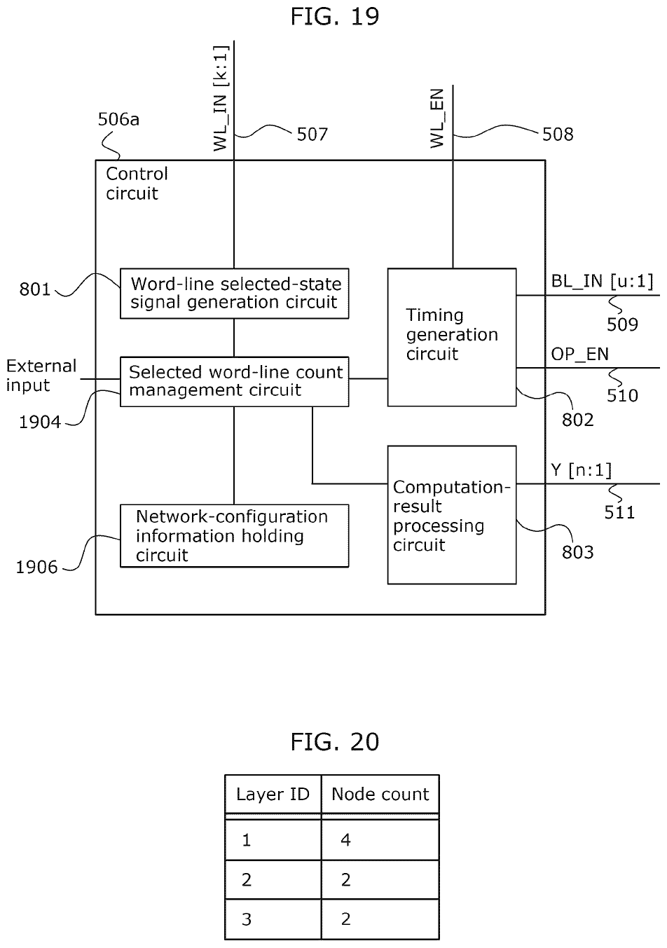

FIG. 19 illustrates a configuration of control circuit 506a included in a neural network computation circuit according to Embodiment 2. Control circuit 506a newly includes network-configuration information holding circuit 1906, as compared to control circuit 506 in FIG. 8.

Network-configuration information holding circuit 1906 stores therein the number of layers in the neural network and the number of nodes in each of the layers, as network configuration information.

FIG. 20 illustrates an example of network configuration information stored in network-configuration information holding circuit 1906 included in the control circuit illustrated in FIG. 19. Here, an example of information stored in network-configuration information holding circuit 1906 in the case of the neural network in FIG. 14 is shown. As layer identification (ID), 1, 2, and 3 are assigned to input layer 1401, hidden layer 1402, and output layer 1403, and the node counts (4, 2, and 2) of the layers are stored.

Selected word-line count management circuit 1904 receives input data from the input layer of the neural network or a result from the previous layer processed by computation-result processing circuit 803 as input data, and transmits the input data as data indicating one or more word lines selected when a multiply-accumulate operation is performed to word-line selected-state signal generation circuit 801.

Further, selected word-line count management circuit 1904 receives, from network-configuration information holding circuit 1906, information corresponding to the node count in a neural network layer for which operation is to be performed out of the network configuration information, and transmits the received information to timing generation circuit 802 as a selected word-line count.

The other configuration is the same as that of control circuit 506 in FIG. 8 in Embodiment 1.

Next, examples of specific operations using a neural network computation circuit according to Embodiment 2 are to be described with reference to FIG. 13 to FIG. 15 and FIG. 19 to FIG. 22.

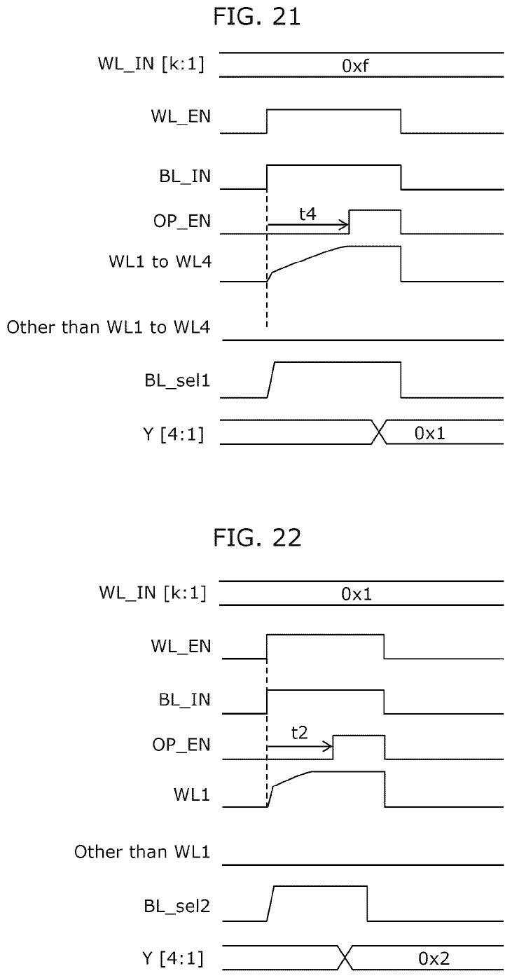

FIG. 21 illustrates operation waveforms (or stated differently, signal waveforms) of hidden layer 1402, which are obtained using the neural network computation circuit according to Embodiment 2. Here, the drawing shows operation waveforms in the case where the neural network computation circuit in FIG. 13 is used for the computation operation of hidden layer 1402 in the neural network configuration in FIG. 14, and the case where input data when the computation operation of hidden layer 1402 is performed is (a4, a3, a2, a1)=(1, 1, 1, 1) illustrated in FIG. 15.

Selected word-line count management circuit 1904 receives data corresponding to input data items a1 to a4 from an external input, and outputs word-line selected-state signal WL_IN [k:1]=0xf to word-line drive circuit 503 via word-line selected-state signal generation circuit 801. Selected word-line count management circuit 1904 receives 4 that is the node count for layer ID1 corresponding to input layer 1401 and is stored in network-configuration information holding circuit 1906, and transmits the count as a selected word-line count (4) to timing generation circuit 802. Timing generation circuit 802 sets delay time t4 corresponding to a set-up time for the selected word-line count (4).

The other circuit operation and the waveforms are the same as those in FIG. 8 and FIG. 16.

FIG. 22 illustrates operation waveforms (or stated differently, signal waveforms) of output layer 1403, which are obtained using the neural network computation circuit according to Embodiment 2. Here, the drawing shows operation waveforms in the case where the neural network computation circuit in FIG. 5 is used for the computation operation of output layer 1403 in the neural network configuration in FIG. 14, and the case where input data when the computation operation of output layer 1403 is performed is (b2, b1)=(0, 1) illustrated in FIG. 15, which is the computation result of hidden layer 1402.

Selected word-line count management circuit 1904 receives data corresponding to input data items b1 and b2 from computation-result processing circuit 803, and outputs word-line selected-state signal WL_IN [k:1]=0x1 to word-line drive circuit 503 via word-line selected-state signal generation circuit 801. Selected word-line count management circuit 1904 receives 2 that is the node count for layer ID2 corresponding to hidden layer 1402 and is stored in network-configuration information holding circuit 1906, and transmits the count as a selected word-line count (2) to timing generation circuit 802.

Timing generation circuit 802 sets delay time t2 corresponding to the selected word-line count (2).

The other circuit operation and the waveforms are the same as those in FIG. 8 and FIG. 17.

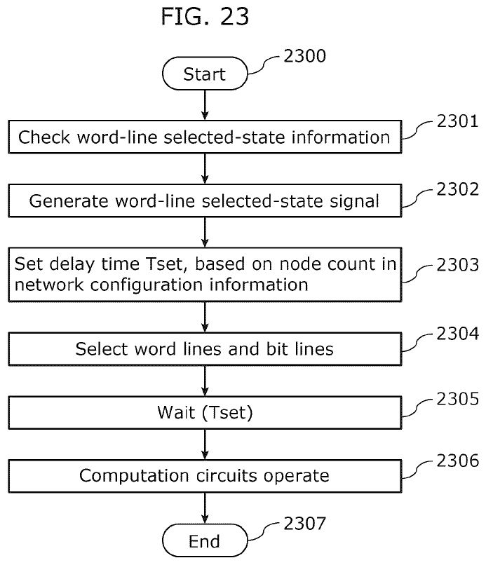

FIG. 23 illustrates an operation flow (that is a control method for a neural network computation circuit) of a neural network operation performed using the neural network computation circuit according to Embodiment 2.

After operation starts (2300), selected word-line count management circuit 1904 checks word-line selected-state information determined by an external input or a computation result of a previous layer that is an input for a layer for which computation operation is to be performed (2301).

Based on the result, word-line selected-state signal generation circuit 801 generates a word-line selected-state signal for determining which word line is to be selected from among plural word lines in the memory array, and outputs the signal to word-line drive circuit 503 (2302).

Next, selected word-line count management circuit 1904 receives the node count for layer ID1 corresponding to the input layer and stored in network-configuration information holding circuit 1906 and transmits the node count as the selected word-line count to timing generation circuit 802, and thus timing generation circuit 802 sets delay time Tset corresponding to a word-line set-up time, based on the received node count in the network configuration information (2303). Then, timing generation circuit 802 outputs word-line activation signal 508 to word-line drive circuit 503 and furthermore outputs column selection signal 509 to column selection circuit 504, and outputs computation-circuit control signal 510 to computation circuits 5051 to 5054 after a lapse of delay time Tset that has been set.

As a result, word-line drive circuit 503 that has received word-line selected-state signal 507 and word-line activation signal 508 selects one or more word lines, and column selection circuit 504 that has received bit-line selection information not illustrated and column selection signal 509 selects one or more bit lines (2304).

Then, after waiting delay time Tset (2305), computation circuits 5051 to 5054 operate (2306) and output computation results 511, so that processing ends (2307).

Through the above operation, delay time Tset until computation circuits 5051 to 5054 are activated after plural word lines for the neural network in FIG. 14 to operate are selected is changed according to the node count that is input in an actual operation. Hence, it is unnecessary to set, as a delay time, a long fixed set-up time for which a total number of word lines of memory array 900 is taken into consideration as with the conventional technology, and thus the speed of computation operation of neurons 100 can be increased.

In Embodiment 1, as shown by the control circuit in FIG. 8 and the operation flow in FIG. 18, the number of word lines selected in an actual operation is counted and delay time Tset is switched. In contrast, in the present embodiment, as shown by the control circuit in FIG. 19 and the operation flow in FIG. 23, the node count in the network configuration information is used, and thus delay time Tset may increase, yet the number of data items of “1” included in input data does not need to be counted, and thus control circuit 506a can be embodied using a simpler circuit than that in Embodiment 1.

As described above, a neural network computation circuit according to the present embodiment includes: a plurality of word lines 501; a plurality of bit lines 502 crossing the plurality of word lines 501; a plurality of memory cells 600 disposed at intersections of the plurality of word lines 501 and the plurality of bit lines 502, the plurality of memory cells 600 including a plurality of semiconductor storage elements each holding a connection weight coefficient of a neural network; word-line drive circuit 503 capable of driving one or more word lines 501 to be placed in a selected state, out of the plurality of word lines 501; column selection circuit 504 capable of selecting one or more bit lines 502 from among the plurality of bit lines 502; computation circuits 5051 to 505n that perform, by using current flowing through one or more bit lines 502 selected by column selection circuit 504, a multiply-accumulate operation on connection weight coefficients held in two or more memory cells and input data represented by driven states of the plurality of word lines 501, and performs neuron computation by performing computation processing of an activation function on a result of the multiply-accumulate operation, two or more memory cells 600 being included in the plurality of memory cells 600 and connected to one or more bit lines 502 selected by column selection circuit 504; word-line selected-state signal generation circuit 801 that generates a word-line selected-state signal indicating one or more word lines 501 to be placed in the selected state by word-line drive circuit 503; timing generation circuit 802 that outputs: word-line activation signal 508 for activating word-line drive circuit 503, based on word-line selected-state signal 507; column selection signal 509 for driving column selection circuit 504; and computation-circuit control signal 510 for activating computation circuits 5051 to 505n; computation-result processing circuit 803 that processes computation result 511 that is an output from computation circuits 5051 to 505n; and selected word-line count management circuit 1904 that manages a selected word-line count that is information relevant to a total number of one or more word lines 501 that are placed in the selected state when computation circuits 5051 to 505n perform the multiply-accumulate operation, and transmits the selected word-line count to timing generation circuit 802. Timing generation circuit 802 sets, according to the selected word-line count, a delay time from when word-line activation signal 508 is output until when computation-circuit control signal 510 is output.

Here, the neural network computation circuit further includes: network-configuration information holding circuit 1906 that stores therein a node count that is a total number of neurons in each of layers of the neural network. The selected word-line count is the node count stored in network-configuration information holding circuit 1906.

Accordingly, the delay time until when the computation circuit is activated after word lines are selected is changed according to the maximum number of word lines that can be actually placed in the selected state, and thus this eliminates the necessity to set, as the delay time, a fixed long set-up time according to the total number of word lines in a memory array as conventional technology required, so that neuron computation is performed at high speed. Furthermore, as compared with Embodiment 1, it is not necessary to count the number of “1” data items included in input data, and thus the circuit can be simplified.

A control method for the neural network computation circuit according to the present embodiment is a control method for a neural network computation circuit that includes: a plurality of word lines 501; a plurality of bit lines 502 crossing the plurality of word lines 501; a plurality of memory cells 600 disposed at intersections of the plurality of word lines 501 and the plurality of bit lines 502, the plurality of memory cells 600 including a plurality of semiconductor storage elements each holding a connection weight coefficient of a neural network; word-line drive circuit 503 capable of driving one or more word lines 501 to be placed in a selected state, out of the plurality of word lines 501; column selection circuit 504 capable of selecting one or more bit lines 502 from among the plurality of bit lines 502; and computation circuits 5051 to 505n that perform, by using current flowing through one or more bit lines 502 selected by column selection circuit 504, a multiply-accumulate operation on input data represented by driven states of the plurality of word lines 501, and perform neuron computation by performing computation processing of an activation function on a result of the multiply-accumulate operation, the control method including: setting a word-line selected state when one or more word lines 501 are driven to be placed in the selected state, out of the plurality of word lines 501; setting a delay time according to a selected word-line count that is information relevant to a total number of one or more word lines 501 that are placed in the selected state when the multiply-accumulate operation is performed; driving one or more word lines 501 according to the word-line selected state; and activating computation circuits 5051 to 505n. The delay time is a period from when the driving is performed until when the activating is performed.

Here, the neural network computation circuit holds, in network-configuration information holding circuit 1906, a node count that is a total number of neurons in each of layers of the neural network as network configuration information. The selected word-line count is the node count. Accordingly, a delay time according to the maximum number of word lines that can be actually placed in a selected state is set.

Accordingly, the delay time until when the computation circuit is activated after word lines are selected is changed according to the maximum number of word lines that can be actually placed in the selected state, and thus this eliminates the necessity to set, as the delay time, a fixed long set-up time according to the total number of word lines in a memory array as conventional technology required, so that neuron computation is performed at high speed. Furthermore, as compared with Embodiment 1, it is not necessary to count the number of “1” data items included in input data, and thus the circuit can be simplified.

The above has described Embodiments 1 and 2 according to the present disclosure, yet the neural network computation circuit according to the present disclosure is not limited to the examples described above, and is effective to variations resulting from, for instance, applying various changes within a scope that does not depart from the gist of the present disclosure.

For example, in the above embodiments, given that the number of computation circuits included as the examples of specific operations is 4 and the maximum number of nodes of a neural network is 4, description has been given using the case where the number of computation circuits is greater than or equal to the node count, or stated differently, the operation of each of the input layer and the hidden layer is completed at one time, yet the number of nodes of the neural network that can operate is not limited to the number of computation circuits that are included.

Furthermore, when the maximum node count of the neural network is greater than the number of computation circuits included, the neural network computation circuit performs operation multiple times, so that the computation operation of each of the layers of the neural network can be performed.

Although only some exemplary embodiments of the present disclosure have been described in detail above, those skilled in the art will readily appreciate that many modifications are possible in the exemplary embodiments without materially departing from the novel teachings and advantages of the present disclosure. Accordingly, all such modifications are intended to be included within the scope of the present disclosure.

### INDUSTRIAL APPLICABILITY

In the neural network computation circuit according to the present disclosure, in operation performed using a neural network configuration, when plural word lines are selected, a word-line set-up time is changed according to the number of word lines selected during the actual operation, and thus the speed of the computation operation of the neural network can be increased. Such utilization is useful to, for example, semiconductor integrated circuits that include artificial intelligence (AI) technology that allows devices to train themselves and make determinations, and useful to electronic devices that includes such integrated circuits.

1. A neural network computation circuit comprising:
a plurality of word lines;
a plurality of bit lines crossing the plurality of word lines;
a plurality of memory cells disposed at intersections of the plurality of word lines and the plurality of bit lines, the plurality of memory cells including a plurality of semiconductor storage elements each holding a connection weight coefficient of a neural network;
a word-line drive circuit capable of driving one or more word lines to be placed in a selected state, out of the plurality of word lines;
a column selection circuit capable of selecting one or more bit lines from among the plurality of bit lines;
a computation circuit that performs, by using current flowing through the one or more bit lines selected by the column selection circuit, a multiply-accumulate operation on connection weight coefficients held in two or more memory cells and input data represented by driven states of the plurality of word lines, and performs neuron computation by performing computation processing of an activation function on a result of the multiply-accumulate operation, the two or more memory cells being included in the plurality of memory cells and connected to the one or more bit lines selected by the column selection circuit;
a word-line selected-state signal generation circuit that generates a word-line selected-state signal indicating the one or more word lines to be placed in the selected state by the word-line drive circuit;
a timing generation circuit that outputs:
a word-line activation signal for activating the word-line drive circuit, based on the word-line selected-state signal;
a column selection signal for driving the column selection circuit; and
a computation-circuit control signal for activating the computation circuit;
a computation-result processing circuit that processes a computation result that is an output from the computation circuit; and
a selected word-line count management circuit that manages a selected word-line count that is information relevant to a total number of the one or more word lines that are placed in the selected state when the computation circuit performs the multiply-accumulate operation, and transmits the selected word-line count to the timing generation circuit,
wherein the timing generation circuit sets, according to the selected word-line count, a delay time from when the word-line activation signal is output until when the computation-circuit control signal is output.

2. The neural network computation circuit according to claim 1,
wherein the selected word-line count is a value obtained by the selected word-line count management circuit counting the total number of the one or more word lines placed in the selected state, the total number being included in data that is input from an outside of the neural network computation circuit or in output data from the computation-result processing circuit.

3. The neural network computation circuit according to claim 1, further comprising:
a network-configuration information holding circuit that stores therein a node count that is a total number of neurons in each of layers of the neural network,
wherein the selected word-line count is the node count stored in the network-configuration information holding circuit.

4. The neural network computation circuit according to claim 1,
wherein the plurality of memory cells each include a variable-resistance storage element, a magnetoresistance storage element, a phase-change storage element, or a charge storage element having a threshold that changes according to an amount of charge stored.

5. A control circuit that controls a neural network computation circuit, the control circuit comprising:
the word-line selected-state signal generation circuit, the timing generation circuit, the computation-result processing circuit, and the selected word-line count management circuit that are included in the neural network computation circuit according to claim 1,
wherein the timing generation circuit sets, according to the selected word-line count, the delay time from when the word-line activation signal is output until when the computation-circuit control signal is output.

6. A control method for a neural network computation circuit that includes:
a plurality of word lines;
a plurality of bit lines crossing the plurality of word lines;
a plurality of memory cells disposed at intersections of the plurality of word lines and the plurality of bit lines, the plurality of memory cells including a plurality of semiconductor storage elements each holding a connection weight coefficient of a neural network;
a word-line drive circuit capable of driving one or more word lines to be placed in a selected state, out of the plurality of word lines;
a column selection circuit capable of selecting one or more bit lines from among the plurality of bit lines; and
a computation circuit that performs, by using current flowing through the one or more bit lines selected by the column selection circuit, a multiply-accumulate operation on input data represented by driven states of the plurality of word lines, and performs neuron computation by performing computation processing of an activation function on a result of the multiply-accumulate operation, the control method comprising:
setting a word-line selected state when the one or more word lines are driven to be placed in the selected state, out of the plurality of word lines;
setting a delay time according to a selected word-line count that is information relevant to a total number of the one or more word lines that are placed in the selected state when the multiply-accumulate operation is performed;
driving the one or more word lines according to the word-line selected state; and
activating the computation circuit,
wherein the delay time is a period from when the driving is performed until when the activating is performed.

7. The control method according to claim 6,
wherein the selected word-line count is a total number of the one or more word lines to be placed in the selected state, the one or more word lines being included in the word-line selected state.

8. The control method according to claim 6,
wherein the neural network computation circuit holds, in a network-configuration information holding circuit, a node count that is a total number of neurons in each of layers of the neural network, as network configuration information, and
the selected word-line count is the node count.
